(19) United States
(12) Patent Application Publication
(10) Pub. No.: US 2004/0121583 A1
(43) Pub. Date: Jun. 24, 2004

(54) Method for forming capping barrier layer over copper feature

(75) Inventors: Tien-I Bao, Hsin-Chu (TW); Syun-Ming Jang, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/324,233

(22) Filed: Dec. 19, 2002

(51) Int. Cl. H01L 21/4763

(52) U.S. Cl. 438/627; 438/648; 438/710

(57) ABSTRACT

A method for forming a capping barrier layer over a metal filled semiconductor feature including providing a semiconductor process wafer including a metal filled feature lined with a first metal diffusion barrier layer; forming a recessed area over the upper portion of the metal filled feature with respect to a feature opening level including an adjacent dielectric layer; blanket depositing a second metal diffusion barrier layer over the recessed area; and, carrying out a chemical mechanical polishing (CMP) process to remove the second metal diffusion barrier layer above the feature opening level.

### FIELD OF THE INVENTION

This invention generally relates to copper filled semiconductor features and more particularly to a method for forming a capping barrier layer to prevent for example, copper ion diffusion through or along an overlying dielectric layer interface leading to time dependent dielectric breakdown.

### BACKGROUND OF THE INVENTION

Planarization is increasingly important in semiconductor manufacturing techniques. As device sizes decrease, the importance of achieving high resolution features through photolithographic processes correspondingly increases thereby placing more severe constraints on the degree of planarity required of a semiconductor wafer processing surface. Excessive degrees of surface non-planarity will undesirably affect the quality of several semiconductor manufacturing process including, for example, photolithographic patterning processes, where the positioning the image plane of the process surface within an increasingly limited depth of focus window is required to achieve high resolution semiconductor feature patterns.

Chemical mechanical polishing (CMP) is increasingly being used as a planarizing process for semiconductor device layers, especially for devices having multi-level design and smaller semiconductor fabrication processes, for example, having line widths below about 0.25 micron. CMP planarization is typically used several different times in the manufacture of a multi-level semiconductor device, including planarizing levels of a device containing both dielectric and metal portions to achieve global planarization for subsequent processing of overlying levels. For example, CMP is used to remove excess metal after filling conductive metal interconnect openings formed in dielectric insulating layers with metal to form features such as vias and trench lines. The vias and trench lines electrically interconnect the several levels and areas within a level that make up a multi-level semiconductor device.

In the formation of metal interconnects, copper is increasingly used for forming such as vias and trench lines since copper has low resistivity and good electromigration resistance compared to other traditional interconnect metals such as aluminum. One problem with the use of copper relates to it relatively high degree of softness making it subject to relatively high differential material removal rates compared to adjacent dielectric insulating oxide materials during planarization processes such as chemical mechanical polishing (CMP). A recurring problem in copper CMP processes is that the simultaneous goal of achieving fast material removal rates of the copper and the underlying barrier layer without erosion of the underlying insulating dielectric layer or dishing of the copper filled feature is difficult to attain. Dishing is defined as the reduced, thickness of the metal feature from the lowest point of the feature relative to the adjacent oxide layer.

For example, in the formation of copper filled features, vias and trench lines are typically formed as part of a damascene process. Although there are several different methods for forming damascene structures, one typical method generally involves patterning and anisotropically etching a semiconductor feature, for example a via opening within an dielectric insulating layer to form closed communication with a conductive area included in an underlying level of the multi-level device. A similar process is then used to pattern and anisotropically etch a trench line opening overlying and encompassing the via opening to form a dual damascene opening structure. The dual damascene structure is then filled with a metal, for example copper, followed by a CMP step to remove excess copper and barrier layers overlying the dielectric insulating layer, also referred to as an inter-metal dielectric (IMD) layer surface, and to planarize the IMD layer surface for subsequent formation of an overlying device level. The process is then repeated in an overlying IMD layer to form a series of stacked conductive lines which electrically communicate between and within the various layers to form a multi-level semiconductor device. Typically, vias and dual damascene structures are stacked above one another to reduce an overall space requirement for patterning a semiconductor device.

Another CMP induced defect is related to the formation of copper interconnect features such as copper filled vias and trenches and the practice of forming a conformal barrier layer within the anisotropically etched features prior to filling with copper. The barrier layer is formed to prevent diffusion of copper into the adjacent IMD layer within which the vias and trench openings are formed. The barrier layer typically includes a refractory metal and/or a refractory metal nitride which typically have a high resistance to copper ion diffusion. After filling of the anisotropically etched features with copper, for example by electroplating, a CMP process is carried out to first remove the excess copper overlying the barrier layer and another CMP process performed to remove the barrier layer overlying the IMD layer. During a portion of the CMP process, for example where both copper and barrier/adhesion material are exposed on the polishing surface, it is believed that a corrosive electrochemical reaction due to charge accumulation on the wafer surface and the presence of two dissimilar metals, for example tantalum and copper, results in corrosion of copper containing features. As a result, due to either or both CMP effects or electrochemical effects, the copper feature invariably exhibits some degree of dishing or the formation of a recess in the copper feature with respect to the surrounding IMD layer.

For example, referring to FIG. 1A is shown a portion of a multi-level semiconductor device including a dual damascene structure e.g., 12 formed in an IMD layer 16. A barrier layer 18A is blanket deposited to line the dual damascene opening followed by a copper deposition process to deposit a copper layer 18B to fill the dual damascene opening.

Referring to FIG. 1B, an expanded portion of dual damascene structure 12 is depicted. A CMP process is first carried out to first remove the excess copper layer 18B overlying the barrier layer 18A, followed by removing the barrier layer 18A overlying the IMD layer 16A. During the CMP process, a recessed area e.g., 20, for example due to dishing, forms over the top portion remaining copper layer portion 18B, including thinning a portion of the barrier layer 18A along the sidewalls of the feature. Subsequently, another dielectric layer e.g., 16B is deposited over the IMD layer 16A to begin the formation of another device level.

One problem with the prior art approach is that deposition of an overlying dielectric layer, e.g., 16B is that the thinning of the barrier layer 18A at the top corners of the feature along the feature sidewall creates an area of reduced resistant to copper diffusion or electromigration. Subsequent copper ion diffusion under the influence of an electric field, also referred to as electromigration, around and/or through the weakened barrier layer area at the feature top corners will adversely affect device reliability leading to time dependent dielectric breakdown (TDDB).

Therefore, there is a need in the semiconductor art to develop a method for reducing or avoiding metal ion diffusion, for example, copper diffusion through or around a top corner portion of a copper filled feature to improve device reliability including reducing time dependent dielectric breakdown (TDDB).

It is therefore an object of the invention to provide a method for reducing or avoiding metal ion diffusion, for example, copper diffusion through or around a top corner portion of a copper filled feature to improve device reliability including reducing time dependent dielectric breakdown (TDDB) while overcoming other shortcomings and deficiencies in the prior art.

### SUMMARY OF THE INVENTION

To achieve the foregoing and other objects, and in accordance with the purposes of the present invention, as embodied and broadly described herein, the present invention provides a method for forming a capping barrier layer over a metal filled semiconductor feature.

In a first embodiment, the method includes providing a semiconductor process wafer including a metal filled feature lined with a first metal diffusion barrier layer; forming a recessed area over the upper portion of the metal filled feature with respect to a feature opening level including an adjacent dielectric layer; blanket depositing a second metal diffusion barrier layer over the recessed area; and, carrying out a chemical mechanical polishing (CMP) process to remove the second metal diffusion barrier layer above the feature opening level.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1B are cross sectional side view representations of a portion of an exemplary copper containing semiconductor feature included in a multi-level semiconductor device showing the thinning of the barrier layer following a copper filled feature manufacturing process according to the prior art.

FIGS. 2A-2E are cross sectional side view representations of an exemplary metal filled semiconductor feature, for example copper, at different stages of manufacture including forming a capping barrier layer according to embodiments of the present invention.

FIGS. 3A-3F are cross sectional side view representations of an exemplary metal filled semiconductor feature, for example copper, at different stages of manufacture including forming a capping barrier layer according to embodiments of the present invention.

FIG. 4 is a process flow diagram including forming a capping barrier layer according to several embodiments of the present invention.

### DETAILED DESCRIPTION OF THE PREFERRED EMBODIMENTS

Although the present invention is explained with respect to the formation of an exemplary dual damascene structure, it will be appreciated that the method of the present invention is equally applicable to any metal filled semiconductor feature including single damascene structures where formation of a capping barrier layer will avoid metal ion diffusion through a top portion of the metal filled feature, for example, a copper filled feature. It will be further be understood that the use of the term ‘copper’ herein includes copper or alloys thereof.

Referring to FIG. 2A, in an exemplary application of the present invention, is shown a cross sectional side view representation of a portion of a semiconductor device included in a semiconductor wafer having an anisotropically etched dual damascene opening including a via portion 20A and an overlying trench line portion 20B. While there are several ways to form a dual damascene structure, one approach involves at least two photolithographic patterning and anisotropic etching steps to first form via openings followed by a similar process to form overlying trench line openings e.g., 20B encompassing one or more via openings, e.g., 20A.

Still referring to FIG. 2A, a first etching stop layer 24, formed of, for example silicon nitride (e.g., Si₃N₄), is provided over a conductive region 21A, for example a copper damascene structure formed in an underlying dielectric insulating layer 21B. Overlying the first etching stop layer 24 is another insulating dielectric layer 26, also referred to as an inter-metal dielectric (IMD) layer. For example, the IMD layer 26 is a low-k (low dielectric constant e.g., less than about 3.2) silicon dioxide based material, for example a carbon doped silicon dioxide, also referred to as organo silicate glass (OSG) and C-oxide. Several commercially available formulations are available for producing the carbon doped oxide, for example, known as SILK™ and BLACK DIAMOND™. Other types of low-k materials suitably used with the method of the present invention include fluorinated silicate glass (FSG) and porous oxides.

It will be appreciated that organic IMD layers may be advantageously used in the method of the present invention-where an oxide based capping layer or anti-reflectance coating (ARC) is provided over the IMD layer. Exemplary organic low-k materials include polyarylene ether, hydrogen silesquioxane (HSQ), methyl silsesquioxane (MSQ), polysilsequioxane, polyimide, benzocyclbbutene, and amorphous Teflon.

Still referring to FIG. 2A, overlying the IMD layer 26 is formed a IMD capping dielectric layer, for example an etching stop layer 28, for example including silicon nitride (e.g., Si₃N₄) and/or silicon oxynitride (e.g., SiON) which may function as both an etching stop and anti-reflectance coating (ARC) layer. For example, the etching stop layer 28 is from about 500 Angstroms to about 1500 Angstroms in thickness.

The dual damascene structure is formed by first sequentially photolithographically patterning and anisotropically etching the via opening 20A through the etching stop layer 28, the IMD layer 26, and at least partially through the first etching stop layer 24 followed by a similar process to photolithographically pattern and anisotropically etch a trench opening 20B through the etching stop layer 28 and a portion of the IMD layer 26 to form a trench opening overlying and encompassing the via opening 20A. It will be appreciated that the trench opening 20B may encompass one or more via openings and that the trench opening and via opening may be formed in separate stacked IMD layers including another etching stop layer formed between the respective IMD layers.

Still referring to FIG. 2A, a barrier layer 30A is blanket deposited to line the dual damascene opening. Preferably the barrier layer 30A includes a refractory metal and/or a respective nitride and/or silicide. For example the barrier layer 30A preferably includes at least one layer of tantalum, titanium, and tungsten, nitrides thereof, and silicide nitrides thereof. For example, the barrier layer preferably includes at least one layer of Ta, TaN, TaSiN, Ti, TiN, TiSiN, and WN. For example, multiple layers including a first refractory metal followed by a refractory metal nitride or silicided metal nitride is suitably used as a barrier layer. The barrier layer 30A is blanket deposited at a thickness of about 50 Angstroms to about 150 Angstroms. The barrier layer 30A serves the purpose of preventing subsequently deposited metal, for example, copper from diffusing into the surrounding IMD layer 26 and improves adhesion of the subsequently deposited metal.

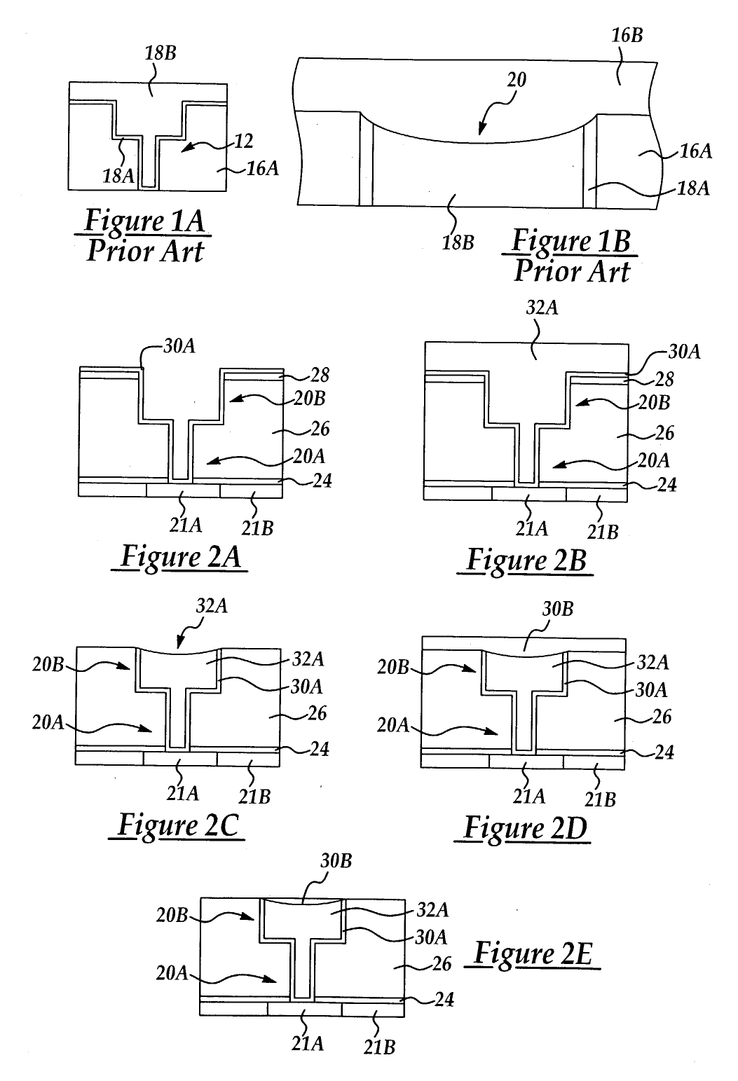

Referring to FIG. 1B, following deposition of barrier layer e.g., 30, a copper layer 32A is electroplated according to a conventional electro-chemical deposition (ECD) process to fill the dual damascene feature 20 including an overlying portion above the trench level. Although other copper filling methods such as PVD and CVD methods may be used, electroplating (electrodeposition) is preferred because of its superior gap-filling and step coverage. Prior to electrodeposition, a seed layer of copper (not shown) is deposited over the barrier layer 30 by, for example by PVD and/or CVD. The copper seed layer is preferably deposited to form a continuous layer over the wafer process surface thereby providing a continuously conductive surface for depositing the bulk of the copper during the ECD process.

Referring to FIG. 2C, a first CMP process is carried out to remove the excess copper layer 32A overlying the barrier layer 30A followed by removal of the barrier layer 30A and at least a portion of the etching stop layer 28. The first CMP process, for example, includes a series of CMP steps including polishing slurries and polishing pads optimized for removal of the various material layers as is known in the art. As shown in FIG. 2C, following the first CMP process, a recessed area 32B due to CMP dishing preferably from about 50 Angstroms to about 500 Angstroms from the feature level (e.g., with respect to an adjacent dielectric layer level) to its most recessed point is formed over the upper portion of the remaining portion of the copper layer 32A making up a copper feature, for example a dual damascene. It has been found that the recessed copper area 32B is typically formed to preferentially erode and thin the barrier layer 30A at the corners of the upper trench portion level of the dual damascene structure.

Referring to FIG. 2D, in a first exemplary embodiment of the present invention, following the first CMP process to produce the recessed copper area 32B over the upper portion of the trench portion of the dual damascene a second barrier layer 30B is blanket deposited over the process wafer surface to included covering the damascene structure and the recessed area 32B. The second barrier layer 30B is preferably deposited to a thickness of about 50 Angstroms to about 500 Angstroms. The second barrier layer may, but need not fill the recessed area 32B, as long as a barrier layer of sufficient thickness is deposited to avoid copper ion diffusion through an upper portion, e.g., thinned first barrier layer corner portion of the copper feature. The second barrier layer 30B is deposited by conventional PVD and/or CVD methods, including nitridation and silicidation methods known in the art. The second barrier layer 30B need not be the same material or multiple layer structure as the first barrier layer 30A, but preferably includes at least one layer of Ta, TaN, TaSiN, Ti, TiN, TiSiN, and WN. For example, the first barrier layer 30A may be formed of a multiple Ta/TaSiN layer while the second barrier 30B is formed of a single layer of TaSiN or TiSiN.

Referring to FIG. 2E, following deposition of the second barrier layer 30B, a second CMP process is carried out to remove the portion of the barrier layer 30B overlying the dual damascene feature level and outside the feature, leaving the recessed area 32B covered by the second barrier layer 30B to a thickness of about 50 Angstroms to about 500 Angstroms. For example, the second CMP process may include CMP polishing slurries and polishing pads optimized for removal of the second barrier layer as are known in the art including a buffing step for removing scratches in, for example, the surface of the exposed dielectric layer underlying the second barrier layer. It is important to substantially remove the second barrier layer 30B outside the copper feature, i.e., above the copper feature level, to prevent electrical bridging or conduction along the second barrier layer between the copper filled features following subsequent deposition of an overlying dielectric layer, for example, another etching stop layer. For example, following the second CMP process, another dielectric layer, for example an etching stop layer is deposited over the dual damascene feature to begin the manufacturing process of another level of the semiconductor device.

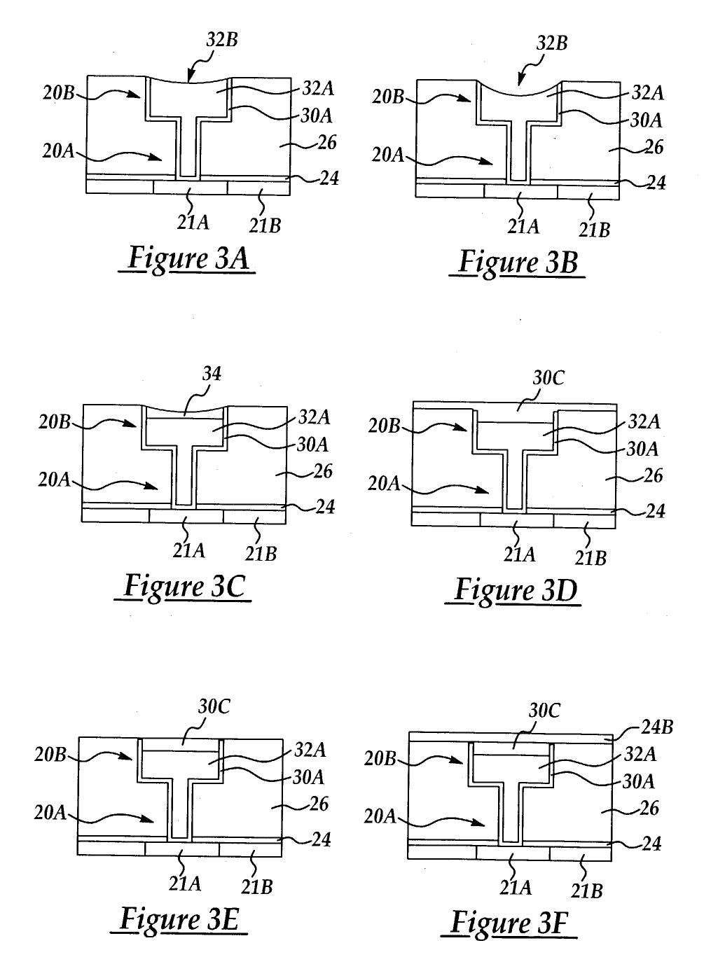

Referring to FIG. 3A, following the first CMP process to produce recessed copper region 32B, referring to FIG. 3B, in a second exemplary embodiment of the present invention, the recessed region 32B is increased in depth, for example preferably having a depth from about from about 50 Angstroms to about 1000 Angstroms measured from the feature level (e.g., with respect to an adjacent dielectric layer level e.g., 26) to its most recessed point to better define the recessed region 32B and provide a sufficient depth for good adhesion and step coverage for deposition of capping barrier layer. In one embodiment, the recessed area 32B may be increased in depth by a third CMP process and/or a wet etching process. For example in a third CMP process, an over polishing step is carried out where an appropriate polishing slurry is used to increase the dishing depth of the recessed area 32B. For example, the polishing slurry may be one optimized for polishing copper features as are known in the art.

Referring to FIG. 3C, in another embodiment, the depth of the recessed area 32B is increased by first oxidizing an upper portion e.g., 34 of the exposed copper filled feature followed by another CMP step or wet etching step to remove the oxidized portion 34 of the copper feature. In one embodiment, the exposed portion of the copper feature is preferably oxidized by an oxygen atom containing plasma treatment for example using an oxygen containing plasma gas source. For example, an oxygen containing plasma gas source including one or more of, for example O₂, CO, CO₂, N₂O, and the like may be used as the plasma gas source for plasma oxidation. Alternatively, the exposed copper feature may be oxidized by baking the process wafer in an oxygen atom containing gaseous ambient for a period of time, for example baking the wafer in an oxygen containing ambient at a temperature of about 100° C. to about 500° C., more preferably about 250° C. to about 350° C. It will be appreciated that a wide variety of gases including oxygen atoms may be used for creating the oxygen containing ambient, for example a gas including at least one of O₂, CO, CO₂, N₂O, H₂O, H₂O₂, and the like may be suitably used. It will be appreciated that the thickness of the oxidized portion of the upper portion of the copper filled feature will depend partly on the temperature of oxidation and the time period of oxidation, i.e., oxidation kinetics. For example, an oxidized thickness portion of about 50 Angstroms to about 1000 Angstroms may suitably be formed for subsequent removal to better define and increase the depth of the recessed portion 32B.

Referring to FIG. 3C, following formation of the oxidized portion of the copper feature to form a predetermined copper oxide thickness, the copper oxide portion 34 is removed by a wet etching process using a copper oxide removing solution. Preferably an acidic copper oxide removing solution is used, preferably having a pH of between about 3.0 and about 5.5. While there are a number of suitable acidic copper oxide removing wet etching solutions known in the art, preferably a solution including a carboxylic acid such as citric acid and/or a dilute solution of HF is used. Alternatively, a commercially available CMP cleaning solution, for example used in a post CMP process to remove copper oxides (e.g., CuO, Cu₂O) may be used. Most preferably a carboxylic acid containing solution is used as it is believed the copper oxide is effectively complexed for subsequent removal by agitation, such as brushing and/or spraying. Preferably the carboxylic acid containing solution is within a temperature range of from about 20° C. to about 90° C.

According to one embodiment of the present invention, the process wafer is subjected to a CMP cleaning step using the copper oxide removal solution. In another embodiment, the process wafer is directly dipped (immersed) into the copper oxide removal solution for a period of time, preferably with a simultaneous source of surface agitation applied. For example, the dipping process may include a simultaneous source of ultrasonic energy such as megasonic agitation applied to agitate the surface and remove loosened copper oxide. Alternatively, following the dipping process, the semiconductor process wafer may be subjected to a brush cleaning process to remove any loosened copper oxide layer particles remaining on the process wafer surface and to clean the process wafer surface. Additionally, the process wafer may be sprayed with the copper oxide removing solution while being simultaneously subjected to brushing action, for example by PVA bristles to minimize surface scratching. Preferably the copper oxide overlayer is contacted with the oxide removal solution for a period of from about 5 to about 90 seconds, more preferably from about 20 to about 60 seconds.

Referring to FIG. 3D, following the wet etching process to remove the copper oxide portion 34, a second barrier layer 30C is blanket deposited by conventional CVD and/or PVD methods including forming a second barrier layer 30C over the recessed area 32B at thickness of about 50 to 500 Angstroms. It will be appreciated that the recessed area 32B may be formed at or below the feature level as long as the second barrier layer 30C is of sufficient thickness, i.e., from about 50 Angstroms to about 500 Angstroms to provide an effective diffusion barrier through a top portion, i.e., corner portion of the feature. The second barrier layer 30C need not be the same material or multiple layer structure as the first barrier layer 30A, but preferably includes at least one layer of Ta, TaN, TaSiN, Ti, TiN, TiSiN, and WN.

Referring to FIG. 3E, following blanket deposition of the second barrier layer 30C, a second CMP process to remove the barrier layer 30C above the feature level and outside the copper line is carried out to form a barrier capping layer overlying the copper feature. For example, a slurry and polishing pad optimized for removal of the barrier layer is used as is known in the art followed by a buffing process to remove scratches in an exposed dielectric layer underlying the barrier layer 30C. Referring to FIG. 3F, following the second CMP process to remove the second barrier layer 30C outside the copper line, another dielectric layer, for example an etching stop layer 24B of silicon nitride is deposited over the process wafer surface including over the barrier capping layer overlying the copper feature.

It has been found, according to the present invention, that forming the second barrier layer over a recessed copper feature, preferably having, for example, a desired thickness of about 50 Angstroms to about 500 Angstroms, effectively overcomes shortcomings in the prior art by increasing the time related to time dependent dielectric breakdown (TDDB) as well as increasing the dielectric breakdown voltage. It is believed that the TDDB according to prior art semiconductor manufacturing processes is caused by what is believed to be due to diffusion of copper ions from the copper filled feature along the interface area of the IMD layer and a subsequently deposited overlying dielectric layer enhanced by thinning of the first barrier layer during a copper feature CMP process according to the prior art. The method of the present invention of depositing a second barrier layer over a recessed area over the copper filled feature to form a capping barrier layer acts to prevent such time dependent copper ion diffusion under an applied voltage and significantly increases the time to dielectric breakdown. In addition, the capping barrier layer according to embodiments of the present invention acts to increase the voltage required to reach dielectric breakdown over a given time period from about 100% to about 300%. Furthermore, the measured leakage current between copper features is reduced from about two to four orders of magnitude at a give applied voltage.

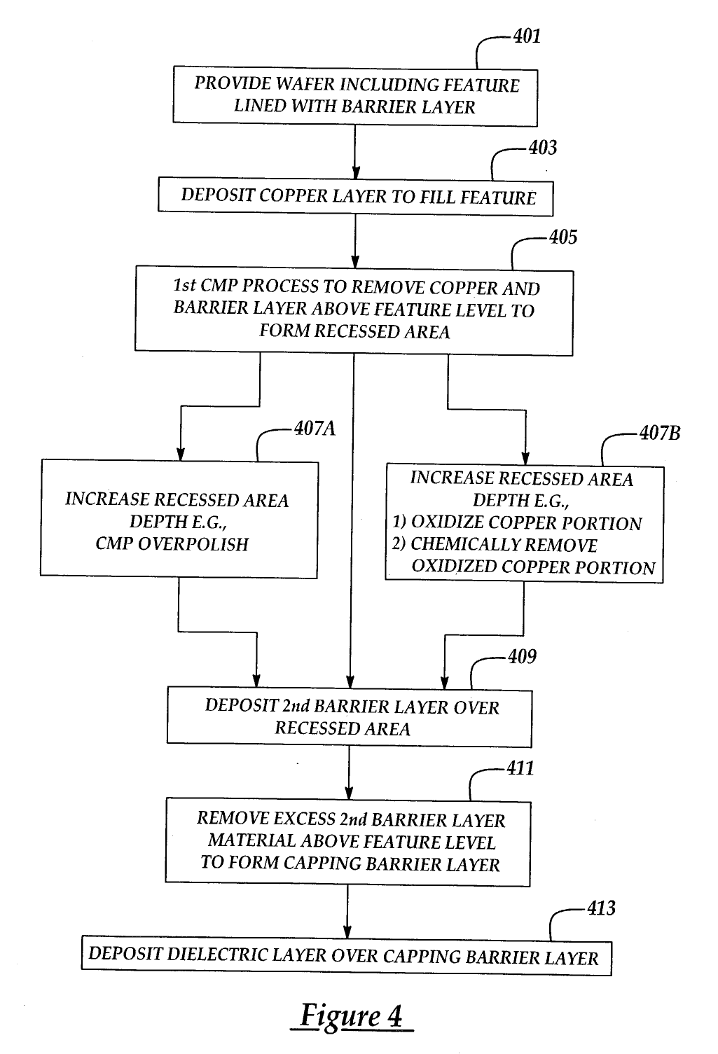

Referring to FIG. 4, is shown a process flow diagram including several of the embodiments of the present invention. In process 401, a feature opening formed in a dielectric insulating layer is provided lined with a first barrier layer at least one of a refractory metal, refractory metal nitride, and a refractory metal silicide nitride. In process 403, a copper layer is blanket deposited to fill the feature opening. In process 405, a first CMP process is carried out to remove the overlying copper layer above the feature level including at least the underlying first barrier layer to form a recessed area in the upper portion of the copper filled feature with respect to the adjacent dielectric layer level (feature level). In optional process 407A, the depth of the recessed area with respect to the adjacent dielectric layer level is increased by a CMP over polish process. In optional process 407B, the depth of the recessed area with respect to the adjacent dielectric layer level (feature level) is increased by oxidizing the upper portion of the copper filled feature to form a copper oxide portion followed by removal of the copper oxide portion. In process 409, following process 405 or optional processes 407A or 407B, a second barrier layer is blanket deposited over the recessed area. In process 411, a second CMP process is carried out to remove the second barrier layer above the feature level to form a capping barrier layer over the copper filled feature. In process 413, a dielectric layer is deposited over the capping barrier layer.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method for forming a capping barrier layer over a metal filled semiconductor feature comprising the steps of:
providing a semiconductor process wafer comprising a metal filled feature lined with a first metal diffusion barrier layer;
forming a recessed area over the upper portion of the metal filled feature with respect to a feature opening level comprising an adjacent dielectric layer;
blanket depositing a second metal diffusion barrier layer over the recessed area; and,
carrying out a chemical mechanical polishing (CMP) process to remove the second metal diffusion barrier layer above the feature opening level.

2. The method of claim 1, wherein the metal is selected from the group consisting of copper, tungsten, and alloys thereof.

3. The method of claim 1, wherein the first metal diffusion barrier layer and the second first metal diffusion barrier layer include at least one material layer selected from the group consisting of refractory metals, refractory metal nitrides, and silicided refractory metal nitrides.

4. The method of claim 3, wherein the at least one material layer is selected from the group consisting of Ti, Ta, W, TiN, TaN, WN, TiSiN, and TaSiN.

5. The method of claim 1, wherein the step of forming a recessed area comprises a first CMP process for removing an overlying metal layer to include the first metal diffusion barrier layer above the feature level opening.

6. The method of claim 5, wherein the step of forming a recessed area further comprises a CMP over polishing process.

7. The method of claim 1, wherein the step of forming a recessed area further comprises forming an oxidized thickness portion of an upper portion of the metal filled feature followed by removing the oxidized thickness portion.

8. The method of claim 7, wherein the oxidized thickness portion is formed by at least one of plasma treating the metal filled feature in an oxygen containing plasma and heating the metal filled feature in the presence of an oxygen containing ambient.

9. The method of claim 8, wherein the oxygen in the oxygen containing plasma and the oxygen containing ambient comprises an oxygen containing species selected from the group consisting of O₂, CO, CO₂, N₂O, H₂O, and H₂O₂.

10. The method of claim 7, wherein the step of removing the oxidized thickness portion comprises contacting the oxidized thickness portion with a metal oxide removing solution.

11. The method of claim 10 wherein the metal oxide comprises copper oxide and the metal oxide removing solution comprises an acidic solution having a pH of about 3.0 to about 5.5.

12. The method of claim 11, wherein the acidic solution comprises at least one of a carboxylic acid and HF.

13. The method of claim 10, wherein contacting the oxidized thickness portion with a metal oxide removing solution comprises at least one of immersing and spraying including an optionally applied source of agitation comprising one of ultrasonic energy, brushing, and contacting with a polishing pad.

14. A method for forming a capping barrier layer over a copper filled semiconductor feature to prevent or reduce copper ion diffusion under an applied electric field comprising the steps of:
providing a semiconductor process wafer comprising a feature opening lined with a blanket deposited first copper diffusion barrier layer;
blanket depositing a copper layer to fill the feature opening to form a copper filled feature;
carrying out a first chemical mechanical polishing (CMP) process to remove at least the copper layer and first copper diffusion barrier layer to form a feature opening level;
forming a recessed area with respect to the feature opening level over the upper portion of the copper filled feature;
blanket depositing a second copper diffusion barrier layer over the copper filled feature; and,
carrying out a second (CMP) process to remove the second copper diffusion barrier layer above the feature opening level.

15. The method of claim 14, wherein the second copper diffusion barrier layer includes at least one material layer selected from the group consisting of Ti, Ta, W, TiN, TaN, WN, TiSiN, and TaSiN.

16. The method of claim 14, wherein the step of forming a recessed area further comprises a copper CMP over polishing process.

17. The method of claim 14, wherein the step of forming a recessed area further comprises forming an oxidized thickness portion comprising an upper portion of the copper filled feature followed by removing the oxidized thickness portion.

18. The method of claim 17, wherein the oxidized thickness portion is formed by at least one of plasma treating the copper filled feature in an oxygen containing plasma and heating the copper filled feature in the presence of an oxygen containing ambient.

19. The method of claim 18, wherein the oxygen in the oxygen containing plasma and the oxygen containing ambient is selected from the group consisting of O₂, CO, CO₂, N₂O, H₂O, and H₂O₂.

20. The method of claim 17, wherein the step of removing the oxidized thickness portion comprises contacting the oxidized thickness portion with a copper oxide removing solution.
